(19) United States
(12) Patent Application Publication
(10) Pub. No.: US 2025/0140705 A1
(43) Pub. Date: May 1, 2025

(54) SEMICONDUCTOR PACKAGE

(71) Applicant: Samsung Electronics Co., Ltd., Suwon-si (KR)

(72) Inventor: Kyuhyeon Choi, Suwon-si (KR)

(21) Appl. No.: 18/749,750

(22) Filed: Jun. 21, 2024

(30) Foreign Application Priority Data
Oct. 30, 2023 (KR) 10-2023-0147066

(51) Int. Cl. H01L 23/538; H01L 21/56; H01L 23/00; H01L 23/31; H01L 23/498; H01L 25/18; H10B 80/00

(52) U.S. Cl. CPC H01L 23/5386; H01L 23/3128; H01L 23/49838; H01L 24/08; H01L 24/16; H01L 25/18; H01L 21/56; H01L 23/49833; H01L 24/32; H01L 24/73; H01L 2224/08225; H01L 2224/16227; H01L 2224/32225; H01L 2224/73204; H01L 2924/1431; H10B 80/00

(57) ABSTRACT

A semiconductor package includes a package substrate, a first semiconductor chip on the package substrate and including a plurality of first through vias, a second semiconductor chip spaced apart from the first semiconductor chip in a lateral direction parallel to an upper surface of the package substrate and including a plurality of second through vias, a third semiconductor chip on the first semiconductor chip, an interposer between the third semiconductor chip and the first semiconductor chip and electrically connecting the first semiconductor chip to the third semiconductor chip, a molding layer between the package substrate and the interposer and on the first semiconductor chip and the second semiconductor chip, a first solder ball between the first semiconductor chip and the interposer, and a second solder ball between the second semiconductor chip and the interposer.

### CROSS-REFERENCE TO RELATED APPLICATIONS

This application is based on and claims priority under 35 U.S.C. § 119 to Korean Patent Application No. 10-2023-0147066, filed on Oct. 30, 2023, in the Korean Intellectual Property Office, the disclosure of which is incorporated by reference herein in its entirety.

### BACKGROUND OF THE INVENTION

The inventive concepts relate to a semiconductor package, and more particularly, to a semiconductor package including an interposer.

As the electronics industry advances rapidly and the demands of users increase, electronic devices are decreasing in size and increasing in function and capacity. Semiconductor packages including a plurality of semiconductor chips may thus be needed. The plurality of semiconductor chips included in a semiconductor package may be highly integrated. However, a case where the high degree of integration is not implemented due to a printed circuit board can occur. To solve such a problem, semiconductor packages that connect a plurality of semiconductor chips to each other by using an interposer are being developed.

### SUMMARY OF THE INVENTION

The inventive concepts provide a semiconductor package including an interposer.

According to aspects of the inventive concepts, there is provided a semiconductor package including a package substrate, a first semiconductor chip on the package substrate and including a plurality of first through vias, a second semiconductor chip spaced apart from the first semiconductor chip in a lateral direction parallel to an upper surface of the package substrate and including a plurality of second through vias, a third semiconductor chip on the first semiconductor chip, an interposer between the third semiconductor chip and the first semiconductor chip and electrically connecting the first semiconductor chip to the third semiconductor chip, a molding layer between the package substrate and the interposer and on the first semiconductor chip and the second semiconductor chip, a first solder ball between the first semiconductor chip and the interposer, and a second solder ball between the second semiconductor chip and the interposer, wherein the interposer includes a first pattern structure that electrically connects the first semiconductor chip to the third semiconductor chip, a second pattern structure that electrically connects the second semiconductor chip to the third semiconductor chip, and a third pattern structure that electrically connects the first semiconductor chip to the second semiconductor chip.

According to aspects of the inventive concepts, there is provided a semiconductor package including a package substrate, a first semiconductor chip on the package substrate and including a plurality of first through vias, a second semiconductor chip spaced apart from the first semiconductor chip in a lateral direction parallel to an upper surface of the package substrate and including a plurality of second through vias, a third semiconductor chip on the first semiconductor chip, an interposer between the first semiconductor chip and the third semiconductor chip and electrically connecting the first semiconductor chip, the second semiconductor chip, and the third semiconductor chip to each other, a plurality of joint balls surrounding the first semiconductor chip and the second semiconductor chip in a plan view, a molding layer between the package substrate and the interposer and on the first semiconductor chip, the second semiconductor chip, and at least one of the plurality of joint balls, a first solder ball between the first semiconductor chip and the interposer, and a second solder ball between the second semiconductor chip and the interposer, wherein the interposer includes a first pattern structure overlapping the first semiconductor chip in a vertical direction perpendicular to the upper surface of the package substrate and electrically connecting the first semiconductor chip to the third semiconductor chip, a second pattern structure overlapping the second semiconductor chip in the vertical direction and electrically connecting the second semiconductor chip to the third semiconductor chip, a third pattern structure overlapping the first semiconductor chip and the third semiconductor chip in the vertical direction and electrically connecting the first semiconductor chip to the second semiconductor chip, and an interposer substrate having the first pattern structure, the second pattern structure, and the third pattern structure therein.

According to aspects of the inventive concepts, there is provided a semiconductor package including a package substrate, a first logic chip on the package substrate and including a plurality of first through vias, a second logic chip spaced apart from the first logic chip in a lateral direction parallel to an upper surface of the package substrate and including a plurality of second through vias, a memory chip on the first logic chip and the second logic chip, the memory chip including an upper surface that is wider in the lateral direction than an upper surface of at least one of the first logic chip or the second logic chip, an interposer between the first logic chip and the memory chip and electrically connecting the first logic chip, the second logic chip, and the memory chip to each other, a plurality of joint balls surrounding the first logic chip and the second logic chip in a plan view, a first solder ball between the first logic chip and the interposer, a second solder ball between the second logic chip and the interposer, and a molding layer between the package substrate and the interposer and on the first logic chip, the second logic chip, at least one of the plurality of joint balls, the first solder ball, and the second solder ball, wherein the interposer includes a first pattern structure overlapping the first logic chip in a vertical direction perpendicular to the upper surface of the package substrate and electrically connecting the first logic chip to the memory chip, a second pattern structure that electrically connects the second logic chip to the memory chip, a third pattern structure that electrically connects the first logic chip to the second logic chip, an external connection pad on a lower surface of the interposer and in contact with one of the plurality of joint balls, an external via electrically connected to the external connection pad, a first connection pad on the lower surface of the interposer and in contact with the first solder ball, a second connection pad on an upper surface of the interposer, and an interposer substrate having the first pattern structure, the second pattern structure, the third pattern structure, the external connection pad, the external via, the first connection pad, and the second connection pad therein.

### BRIEF DESCRIPTION OF THE DRAWINGS

Embodiments will be more clearly understood from the following detailed description taken in conjunction with the accompanying drawings, in which:

FIG. 1 is a plan view of a semiconductor package according to some embodiments;

FIG. 2 is a cross-sectional view taken along line A-A′ of FIG. 1;

FIG. 3 is an enlarged view of a region P1 of FIG. 2;

FIG. 4 is a cross-sectional view of a semiconductor package according to some embodiments;

FIG. 5 is a cross-sectional view of a semiconductor package according to some embodiments;

FIG. 6 is a cross-sectional view of a semiconductor package according to some embodiments;

FIG. 7 is an enlarged view of a region P2 of FIG. 6;

FIG. 8 is a cross-sectional view of a semiconductor package according to some embodiments;

FIGS. 9 to 14 are cross-sectional views illustrating in sequence a method of manufacturing a semiconductor package, according to some embodiments;

FIGS. 15 to 17 are cross-sectional views illustrating in sequence a method of manufacturing a semiconductor package, according to some embodiments; and

FIGS. 18 to 20 are cross-sectional views illustrating in sequence a method of manufacturing a semiconductor package, according to some embodiments.

### DETAILED DESCRIPTION

Hereinafter, example embodiments will be described in detail with reference to the accompanying drawings. However, the inventive concepts are not limited to the following illustrated embodiments but may be embodied in different forms. The following embodiments are provided for sufficiently providing the scope of the inventive concepts to those of ordinary skill in the art.

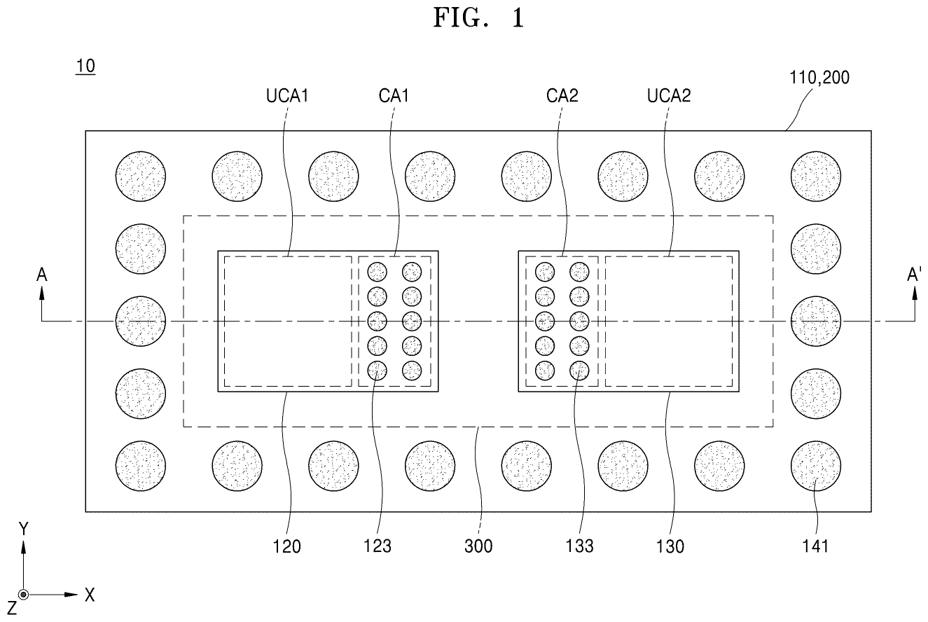

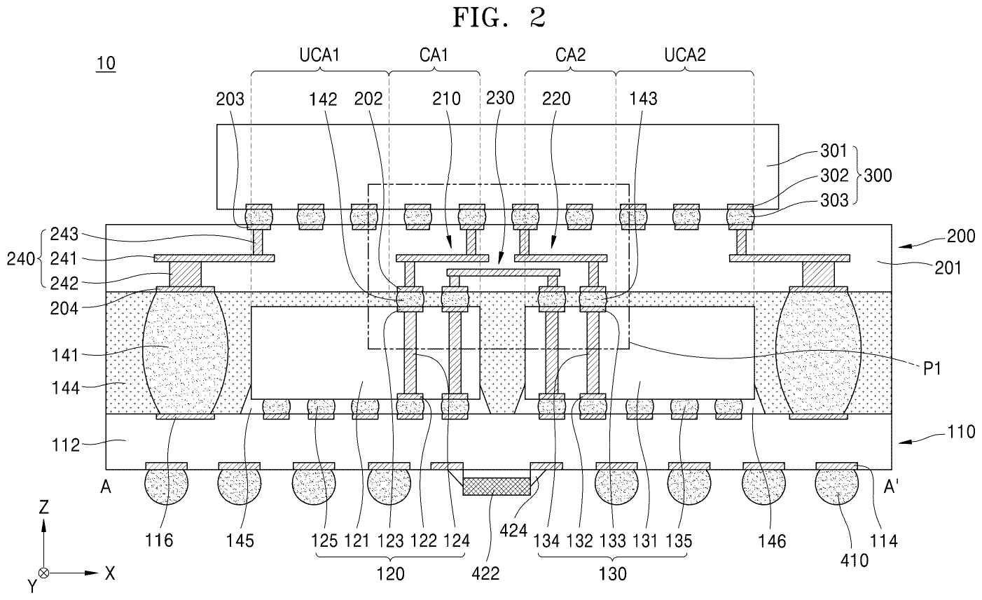

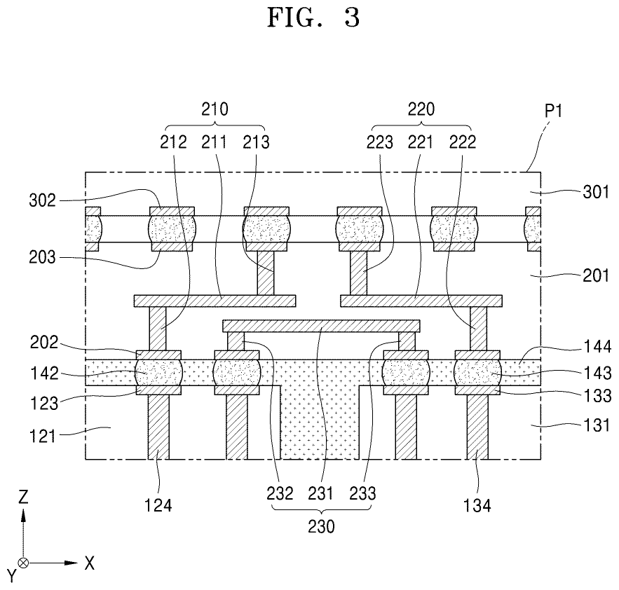

FIG. 1 is a plan view of a semiconductor package 10 according to some embodiments, and FIG. 2 is a cross-sectional view taken along line A-A′ of FIG. 1. Also, FIG. 3 is an enlarged view of a region P1 of FIG. 2.

Referring to FIGS. 1, 2, and 3, the semiconductor package 10 may include a package substrate 110, first and second semiconductor chips 120 and 130 mounted on the package substrate 110, joint balls 141, first and second solder balls 142 and 143, a molding layer 144, first and second under-fill material layers 145 and 146, an interposer 200, a third semiconductor chip 300, and external connection terminals 410.

The package substrate 110 may be, for example, a printed circuit board (PCB). The package substrate 110 may include a substrate base 112 including at least one material selected from among phenol resin, epoxy resin, and polyimide. Also, the package substrate 110 may include substrate lower pads 114 disposed on a lower surface of the substrate base 112 and substrate upper pads 116 disposed on an upper surface of the substrate base 112. Although not shown in detail, an internal wiring pattern configured to electrically connect the substrate lower pad 114 with the substrate upper pad 116 may be formed in the substrate base 112. The internal wiring pattern may include a line pattern which extends in a horizontal direction (an X direction or a Y direction) in the package substrate 110 and a via pattern which extends in a vertical direction (a Z direction) in the package substrate 110.

For example, the substrate lower pad 114 and the substrate upper pad 116 may each include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), rhodium (Rh), or an alloy thereof.

The substrate lower pad 114 may be a pad on which the external connection terminal 410 is attached, and the substrate upper pad 116 may be a pad on which the joint ball 141 and first and second chip connection terminals 125 and 135 such as a micro bump are attached. The external connection terminal 410 may be, for example, a solder ball. The external connection terminal 410 may electrically and physically connect the semiconductor package 10 with an external device. As used herein, “an element A connected to an element B” (or similar language) means that the element A is physically and/or electrically connected to the element B.

In some embodiments, at least one passive device 422 may be attached on a lower surface of the package substrate 110. The at least one passive device 422 may be a surface-mount device (SMD). For example, the at least one passive device 422 may be a capacitor or a resistor. A terminal portion of the at least one passive device 422 may be electrically connected with the substrate lower pad 114 through a device connection terminal 424 disposed on the substrate lower pad 114. In some embodiments, the at least one passive device 422 may be in (e.g., may be buried in) the package substrate 110.

The first semiconductor chip 120 may be mounted on the package substrate 110. The first semiconductor chip 120 may be disposed between the package substrate 110 and the interposer 200 in the vertical direction (the Z direction) perpendicular to an upper surface of the package substrate 110.

According to some embodiments, the first semiconductor chip 120 may include a first chip body 121, first lower chip pads 122, first upper chip pads 123, first through vias 124, and first chip connection terminals 125.

The first chip body 121 may include an active surface and an inactive surface, which are opposite to each other. The first chip body 121 may include silicon, for example, crystalline silicon, polycrystalline silicon, or amorphous silicon. The first semiconductor chip 120 may include a semiconductor device layer which is formed on the active surface of the first chip body 121. The first semiconductor chip 120 may include a lower surface and an upper surface which are opposite to each other, and the first lower chip pad 122 may be provided on the lower surface of the first semiconductor chip 120. The lower surface of the first semiconductor chip 120 may be a surface which is adjacent to the active surface of the first chip body 121, and the upper surface of the first semiconductor chip 120 may be a surface which is adjacent to the inactive surface of the first chip body 121. The first upper chip pad 123 may be provided on the upper surface of the first semiconductor chip 120. The first through via 124 may provide a path which passes (i.e., extends) through the first chip body 121 in the vertical direction (the Z direction) and connects the first lower chip pad 122 with the first upper chip pad 123. For example, the first through via 124 may include a through-silicon-via (TSV). Also, the first upper chip pad 123 of the first semiconductor chip 120 may be electrically connected with the semiconductor device layer through the first through via 124 provided in the first semiconductor chip 120.

In some embodiments, the first semiconductor chip 120 may be a non-memory chip. For example, the first semiconductor chip 120 may be a logic chip and may include an artificial intelligence (AI) semiconductor, a microprocessor, a graphics processor, a signal processor, a network processor, a chipset, an audio codec, a video codec, and/or an application processor.

The first semiconductor chip 120 may be mounted on the package substrate 110 by a face-down scheme or a flip chip scheme. That is, the first semiconductor chip 120 may be mounted on the package substrate 110 so that the lower surface of the first semiconductor chip 120, where the first lower chip pad 122 is provided, faces the package substrate 110. The first lower chip pad 122 of the first semiconductor chip 120 may be electrically connected with the substrate upper pad 116 through the first chip connection terminal 125. Also, the first upper chip pad 123 of the first semiconductor chip 120 may be electrically connected with an interposer substrate 201 through the first solder ball 142. Each of the first lower chip pad 122 and the first upper chip pad 123 of the first semiconductor chip 120 may be used as a terminal for transferring an input/output (I/O) data signal of the first semiconductor chip 120 or a terminal for power and/or a ground of the first semiconductor chip 120.

For example, the first lower chip pad 122, the first upper chip pad 123, and the first through via 124 may each include a metal, such as Cu, Al, W, Ti, Ta, In, Mo, Mn, Co, Sn, Ni, Mg, Re, Be, Ga, Ru, or an alloy thereof.

The molding layer 144 may be provided on the package substrate 110. The molding layer 144 may be between (e.g., may be filled between) the package substrate 110 and the interposer 200. The molding layer 144 may protect the package substrate 110, the first and second semiconductor chips 120 and 130, the joint ball 141, the first and second solder balls 142 and 143, and the interposer 200 from an external environment. The molding layer 144 may be formed to be on (e.g., to cover) at least a portion of each of the package substrate 110, the first and second semiconductor chips 120 and 130, the joint ball 141, the first and second solder balls 142 and 143, and the interposer 200. For example, the molding layer 144 may be on (e.g., may cover) the upper surface of the package substrate 110, a sidewall and an upper surface of each of the first and second semiconductor chips 120 and 130, a sidewall of the joint ball 141, a sidewall of each of the first and second solder balls 142 and 143, and a lower surface of the interposer 200. Also, the molding layer 144 may be in a gap between (e.g., may fill a gap between) a lower surface of the interposer 200 and an upper surface of the first semiconductor chip 120 and a gap between the lower surface of the interposer 200 and an upper surface of the second semiconductor chip 130.

In some embodiments, a supply process of supplying an insulating filler included in the molding layer 144 between the package substrate 110 and the interposer 200 and a curing process of curing the insulating filler may be performed for forming the molding layer 144.

In some embodiments, the molding layer 144 may include epoxy-group molding resin or polyimide-group molding resin. For example, the molding layer 144 may include an epoxy molding compound (EMC).

The first under-fill material layer 145 surrounding the first chip connection terminal 125 may be between (e.g., may be filled between) the first semiconductor chip 120 and the package substrate 110. For example, the first under-fill material layer 145 may include epoxy resin formed by a capillary under-fill process. In some embodiments, the first under-fill material layer 145 may be a non-conductive film. However, in some embodiments, the molding layer 144 may be directly filled in a gap between the first semiconductor chip 120 and the package substrate 110 by using a molded under-fill process. In this case, the first under-fill material layer 145 may be omitted. It will be understood that “an element A surrounds an element B” (or similar language) as used herein means that the element A is at least partially around the element B but does not necessarily mean that the element A completely encloses the element B.

According to some embodiments, the second semiconductor chip 130 may be mounted on the package substrate 110. The second semiconductor chip 130 may be disposed between the package substrate 110 and the interposer 200 in the vertical direction (the Z direction) perpendicular to the upper surface of the package substrate 110. In this case, the second semiconductor chip 130 may be arranged spaced apart from the first semiconductor chip 120 in a lateral direction (for example, a first horizontal direction (an X direction) or a second horizontal direction (a Y direction)). For example, the first horizontal direction (the X direction) and the second horizontal direction (the Y direction) may be parallel to an upper surface of the package substrate 110.

The second semiconductor chip 130 may include a second chip body 131, second lower chip pads 132, second upper chip pads 133, second through vias 134, and second chip connection terminals 135. The second semiconductor chip 130 may be substantially the same as the first semiconductor chip 120. Accordingly, the above description among common descriptions of the first semiconductor chip 120 and the second semiconductor chip 130 may be omitted to avoid repeated descriptions.

The second chip body 131 may include an active surface and an inactive surface, which are opposite to each other. The second chip body 131 may include substantially the same material as that of the first chip body 121 and may have the same configuration and structure.

The second through via 134 may provide a path which passes (i.e., extends) through the second chip body 131 in the vertical direction (the Z direction) and connects the second lower chip pad 132 with the second upper chip pad 133. For example, the second through via 134 may include a TSV. The second upper chip pad 133 of the second semiconductor chip 130 may be electrically connected with the semiconductor device layer through the second through via 134 provided in the second semiconductor chip 130.

The upper surface of the first semiconductor chip 120 may include a first connection region CA1 and a first non-connection region UCA1, which are defined as sections with respect to a horizontal plane (e.g., in the X direction). Also, an upper surface of the second semiconductor chip 130 may include a second connection region CA2 and a second non-connection region UCA2. In FIG. 1, each of the first connection region CA1, the first non-connection region UCA1, the second connection region CA2, and the second non-connection region UCA2 is illustrated in a quadrilateral shape, but the inventive concepts are not limited thereto.

The first connection region CA1 may be defined as a region where a plurality of the first through vias 124 are arranged. For example, the first connection region CA1 may be a region that overlaps the plurality of first through vias 124 in the vertical direction (the Z direction). An electrical path may be implemented up to the first semiconductor chip 120 and the interposer 200 from the package substrate 110 through the plurality of first through vias 124 arranged in the first connection region CA1. Also, the second connection region CA2 may be defined as a region where a plurality of the second through vias 134 are arranged. For example, the second connection region CA2 may be a region that overlaps the plurality of second through vias 134 in the vertical direction (the Z direction). An electrical path may be implemented up to the second semiconductor chip 130 and the interposer 200 from the package substrate 110 through the plurality of second through vias 134 arranged in the second connection region CA2. The first non-connection region UCA1 may be defined as a region where the first through vias 124 are not arranged. For example, the first non-connection region UCA1 may be a region other than the first connection region CA1, and may be a region that does not overlap the plurality of first through vias 124 in the vertical direction (the Z direction). Likewise, the second non-connection region UCA2 may be defined as a region where the second through vias 134 are not arranged. For example, the second non-connection region UCA2 may be a region other than the second connection region CA2, and may be a region that does not overlap the plurality of second through vias 134 in the vertical direction (the Z direction). As used herein, “an element A overlaps an element B in a direction X” (or similar language) means that there is at least one straight line that extends in the direction X and intersects both the elements A and B.

According to some embodiments, the first connection region CA1 may be disposed closer to the second semiconductor chip 130 than the first non-connection region UCA1. Also, the second connection region CA2 may be disposed closer to the first semiconductor chip 120 than the second non-connection region UCA2. An area of the first connection region CA1 may be less than that of the first non-connection region UCA1, and an area of the second connection region CA2 may be less than that of the second non-connection region UCA2. For example, the first non-connection region UCA1 may be wider than the first connection region CA1 in a lateral direction (e.g., the X direction), and the second non-connection region UCA2 may be wider than the second connection region CA2 in the lateral direction (e.g., the X direction).

The first solder ball 142 and the first upper chip pad 123 may not be disposed on the first non-connection region UCA1 where the first through via 124 is not arranged. Likewise, the second solder ball 143 and the second upper chip pad 133 may not be disposed on the second non-connection region UCA2 where the second through via 134 is not arranged. A solder ball and a pad may thus be disposed on only the first connection region CA1 and the second connection region CA2 which provide an electrical path, thereby decreasing the manufacturing cost of the semiconductor package 10. Accordingly, the first non-connection region UCA1 and the second non-connection region UCA2 may be completely covered by the molding layer 144.

In some embodiments, the second semiconductor chip 130 may be a non-memory chip. For example, the second semiconductor chip 130 may be a logic chip and may include an artificial intelligence (AI) semiconductor, a microprocessor, a graphics processor, a signal processor, a network processor, a chipset, an audio codec, a video codec, and/or an application processor.

The second semiconductor chip 130, like the first semiconductor chip 120, may be mounted on the package substrate 110 by the face-down scheme or the flip chip scheme. That is, the second semiconductor chip 130 may be mounted on the package substrate 110 so that the lower surface of the second semiconductor chip 130, where the second lower chip pad 132 is provided, faces the package substrate 110. Each of the second lower chip pad 132 and the second upper chip pad 133 of the second semiconductor chip 130 may be used as a terminal for transferring an I/O data signal of the second semiconductor chip 130 or a terminal for power and/or a ground of the second semiconductor chip 130.

According to some embodiments, the joint ball 141 may electrically connect the package substrate 110 with the interposer 200. The joint ball 141 may be spaced apart from the sidewall of the first semiconductor chip 120 and/or the second semiconductor chip 130 in the horizontal direction (the X direction and/or the Y direction) and may have a pillar shape which extends between the package substrate 110 and the interposer 200. A lower surface of the joint ball 141 may contact the substrate upper pad 116 of the package substrate 110, and an upper surface of the joint ball 141 may contact an external connection pad 204 of the interposer 200. The joint ball 141 may include, for example, a conductive material such as Sn, lead (Pb), silver (Ag), Cu, or an alloy thereof. The joint balls 141 may surround the first semiconductor chip 120 and the second semiconductor chip 130 with respect to a horizontal plane (e.g., in the X direction and/or the Y direction). For example, the joint balls 141 may surround the first semiconductor chip 120 and the second semiconductor chip 130 in a plan view (see FIG. 1).

The joint ball 141 may have a size which is relatively greater than that of the first solder ball 142 and/or the second solder ball 143. Also, the joint ball 141 may be a ball attached on the substrate upper pad 116 instead of a conductive post formed by a plating process or the like, and thus, may not have a tapered shape or a circular pillar shape. In detail, a lower portion of the joint ball 141 may have a diameter which decreases toward the package substrate 110, and an upper portion of the joint ball 141 may have a roly-poly shape where a diameter decreases toward the interposer 200. For example, opposing sidewalls of the joint ball 141 may have a rounded convex shape. As used herein, the term “diameter” may also be used interchangeably with the term “width”. For example, “a diameter of an element A” (or similar language) as used herein may refer to the width of the element A in a lateral direction (the X direction and/or the Y direction).

According to some embodiments, the first solder ball 142 may electrically connect the first semiconductor chip 120 with the interposer 200, and the second solder ball 143 may electrically connect the second semiconductor chip 130 with the interposer 200. The first solder ball 142 may be disposed in the first connection region CA1 of the upper surface of the first semiconductor chip 120, and the second solder ball 143 may be disposed in the second connection region CA2 of the upper surface of the second semiconductor chip 130. A lower portion of the first solder ball 142 may be attached on the first upper chip pad 123 of the first semiconductor chip 120, and an upper portion of the first solder ball 142 may be attached on a first connection pad 202 of the interposer 200. A lower portion of the second solder ball 143 may be attached on the second upper chip pad 133 of the second semiconductor chip 130, and an upper portion of the second solder ball 143 may be attached on the first connection pad 202 of the interposer 200. The first solder ball 142 and the second solder ball 143 may include, for example, a conductive material such as Sn, Pb, Ag, Cu, or an alloy thereof.

The first solder ball 142 and the second solder ball 143 may be balls attached on the first upper chip pad 123 and the second upper chip pad 133 instead of a conductive post formed by a plating process or the like, and thus, may not have a tapered shape or a circular pillar shape. In detail, a lower portion of each of the first solder ball 142 and the second solder ball 143 may have a diameter which decreases toward the package substrate 110, and an upper portion of each of the first solder ball 142 and the second solder ball 143 may have a diameter which decreases toward the interposer 200. For example, opposing sidewalls of the first solder ball 142 and opposing sidewalls of the second solder ball 143 may have a rounded convex shape.

The interposer 200 may be disposed on the package substrate 110, the first semiconductor chip 120, and the second semiconductor chip 130. The interposer 200 may include an interposer substrate 201. The interposer substrate 201 may have an approximately plate shape and may include an upper surface and a lower surface, which are opposite to each other. The interposer 200 may include first and second connection pads 202 and 203, the external connection pads 204, a first pattern structure 210, a second pattern structure 220, a third pattern structure 230, and an external pattern structure 240. For example, the first and second connection pads 202 and 203, the external connection pads 204, the first pattern structure 210, the second pattern structure 220, the third pattern structure 230, and the external pattern structure 240 may be in the interposer substrate 201.

The interposer substrate 201 may be, for example, a printed circuit board (PCB). In this case, the interposer substrate 201 may be a PCB including substantially the same material as that of the package substrate 110. The interposer substrate 201 may include at least one material selected from among phenol resin, epoxy resin, and polyimide. For example, the interposer substrate 201 may include at least one material selected from among polyimide, frame retardant 4 (FR-4), tetrafunctional epoxy, polyphenylene ether, epoxy/polyphenylene oxide, bismaleimide triazine (BT), thermount, cyanate ester, polyimide, and liquid crystal polymer.

The first connection pad 202 of the interposer 200 may be disposed on a lower surface of the interposer substrate 201, and the second connection pad 203 of the interposer 200 may be disposed on an upper surface of the interposer substrate 201. Also, the external connection pad 204 may be disposed on the lower surface of the interposer substrate 201 like the first connection pad 202, and with respect to a horizontal plane, the external connection pad 204 may be disposed at an outer portion of the lower surface of the interposer substrate 201. For example, the first connection pad 202, the second connection pad 203, and the external connection pad 204 may each include a metal, such as Cu, Al, W, Ti, Ta, In, Mo, Mn, Co, Sn, Ni, Mg, Re, Be, Ga, Ru, or an alloy thereof.

The first connection pad 202 may be a pad on which the first solder ball 142 and the second solder ball 143 are attached, and the second connection pad 203 may be a pad on which a third chip connection terminal 303 of the third semiconductor chip 300 is attached. Also, the external connection pad 204 may be a pad on which the joint ball 141 is attached. According to some embodiments, the third semiconductor chip 300 may include a third chip body 301, third lower chip pads 302, and the third chip connection terminals 303. For example, an upper surface of the third semiconductor chip 300 may be wider than respective upper surfaces of the first semiconductor chip 120 and the second semiconductor chip 130 in a lateral direction (the X direction and/or the Y direction). In some embodiments, the third semiconductor chip 300 may be a memory chip.

The interposer 200 may include the first pattern structure 210, the second pattern structure 220, the third pattern structure 230, and the external pattern structure 240. Hereinafter, the pattern structures will be described in greater detail.

The first pattern structure 210 may be configured to electrically connect the first semiconductor chip 120 with the third semiconductor chip 300. For example, the first pattern structure 210 may be electrically connected between the first semiconductor chip 120 and the third semiconductor chip 300. A connection relationship configured by the first pattern structure 210 may be a vertical connection relationship. In this case, the first pattern structure 210 may overlap the first semiconductor chip 120 in the vertical direction (the Z direction) and may not overlap the second semiconductor chip 130 in the vertical direction (the Z direction).

The first pattern structure 210 may include a first wiring pattern 211, a first via 212, and a second via 213 (e.g., see FIG. 3). The first wiring pattern 211 may be a conductive pattern which extends longitudinally in the lateral direction (the X direction and/or the Y direction). The first via 212 may extend from one end portion of the first wiring pattern 211 and may be connected with the first connection pad 202. In this case, the first connection pad 202 facing the first via 212 may be the first connection pad 202 on which the first solder ball 142 is attached. Therefore, the first via 212 may extend toward the first solder ball 142 in the vertical direction (the Z direction). The second via 213 may extend from the other end portion of the first wiring pattern 211, which is opposite to the one end portion where the first via 212 is formed, and may be connected with the second connection pad 203. In this case, the second connection pad 203 facing the second via 213 may be the second connection pad 203 on which the third chip connection terminal 303 is attached.

The second pattern structure 220 may be configured to electrically connect the second semiconductor chip 130 with the third semiconductor chip 300. For example, the second pattern structure 220 may be electrically connected between the second semiconductor chip 130 and the third semiconductor chip 300. A connection relationship configured by the second pattern structure 220 may be a vertical connection relationship. In this case, the second pattern structure 220 may overlap the second semiconductor chip 130 in the vertical direction (the Z direction) and may not overlap the first semiconductor chip 120 in the vertical direction (the Z direction).

The second pattern structure 220 may include a second wiring pattern 221, a third via 222, and a fourth via 223 (e.g., see FIG. 3). The second wiring pattern 221 may be a conductive pattern which extends longitudinally in the lateral direction (the X direction and/or the Y direction). The third via 222 may extend from one end portion of the second wiring pattern 221 and may be connected with the first connection pad 202. In this case, the first connection pad 202 facing the third via 222 may be the first connection pad 202 on which the second solder ball 143 is attached. Therefore, the third via 222 may extend toward the second solder ball 143 in the vertical direction (the Z direction). The fourth via 223 may extend from the other end portion of the second wiring pattern 221, which is opposite to the one end portion where the third via 222 is formed, and may be connected with the second connection pad 203. In this case, the second connection pad 203 facing the fourth via 223 may be the second connection pad 203 on which the third chip connection terminal 303 is attached.

The third pattern structure 230 may be configured to electrically connect the first semiconductor chip 120 with the second semiconductor chip 130. For example, the third pattern structure 230 may be electrically connected between the first semiconductor chip 120 and the second semiconductor chip 130. A connection relationship configured by the third pattern structure 230 may be a vertical connection relationship. In this case, the third pattern structure 230 may overlap the first semiconductor chip 120 and the second semiconductor chip 130 in the vertical direction (the Z direction). That is, with respect to a horizontal plane, the third pattern structure 230 may be disposed over the first semiconductor chip 120 and the second semiconductor chip 130. For example, the third pattern structure 230 may be between the first pattern structure 210 and the second pattern structure 220.

The third pattern structure 230 may include a third wiring pattern 231, a fifth via 232, and a sixth via 233 (e.g., see FIG. 3). In this case, the third wiring pattern 231 may be a conductive pattern which extends longitudinally in the lateral direction (the X direction and/or the Y direction). The fifth via 232 may extend from one end portion of the third wiring pattern 231 and may be connected with the first connection pad 202. In this case, the first connection pad 202 connected with the fifth via 232 may be the first connection pad 202 on which the first solder ball 142 is attached. Therefore, the fifth via 232 may extend toward the first solder ball 142 in the vertical direction (the Z direction). The sixth via 233 may extend from the other end portion of the third wiring pattern 231, which is opposite to the one end portion where the fifth via 232 is formed, and may be connected with the first connection pad 202. In this case, the first connection pad 202 connected with the sixth via 233 may be the first connection pad 202 on which the second solder ball 143 is attached.

According to some embodiments, the interposer 200 may provide a connection relationship between the third semiconductor chip 300 and the first semiconductor chip 120, and/or may provide a connection relationship between the third semiconductor chip 300 and the second semiconductor chip 130. The connection relationship may physically be a vertical connection relationship (e.g., in the Z direction). Also, the interposer 200 may provide a connection relationship between the first semiconductor chip 120 and the second semiconductor chip 130. The connection relationship may physically be a horizontal connection relationship (e.g., in the X direction). Accordingly, the interposer 200 may provide a vertical wiring structure and a horizontal wiring structure, and thus, a connection distance between semiconductor chips provided in the semiconductor package 10 may be reduced.

The external pattern structure 240 may be configured to electrically connect the joint ball 141 with the third semiconductor chip 300. For example, the external pattern structure 240 may be electrically connected between the joint ball 141 and the third semiconductor chip 300. The external pattern structure 240 may be disposed farther away from a center (e.g., a horizontal center point) of the semiconductor package 10 than the first semiconductor chip 120 and the second semiconductor chip 130.

The external pattern structure 240 may include an external pattern 241, a first external via 242, and a second external via 243. The external pattern 241 may be a conductive pattern which extends longitudinally in the lateral direction (the X direction and/or the Y direction). The first external via 242 may extend from one end portion of the external pattern 241 and may be connected with the external connection pad 204 contacting the joint ball 141. Also, the second external via 243 may be connected with the second connection pad 203 and may extend from the other end portion of the external pattern 241, which is opposite to the one end portion where the first external via 242 is formed. A diameter of the joint ball 141 connected with the first external via 242 may be greater than that of the third chip connection terminal 303 connected with the second external via 243, and thus, a diameter of the first external via 242 may be greater than that of the second external via 243. Likewise, a diameter of the joint ball 141 may be greater than that of each of the first solder ball 142 and the second solder ball 143, and thus, a diameter of the first external via 242 may be greater than a diameter of the first via 212, a diameter of the third via 222, a diameter of the fifth via 232, and a diameter of the sixth via 233.

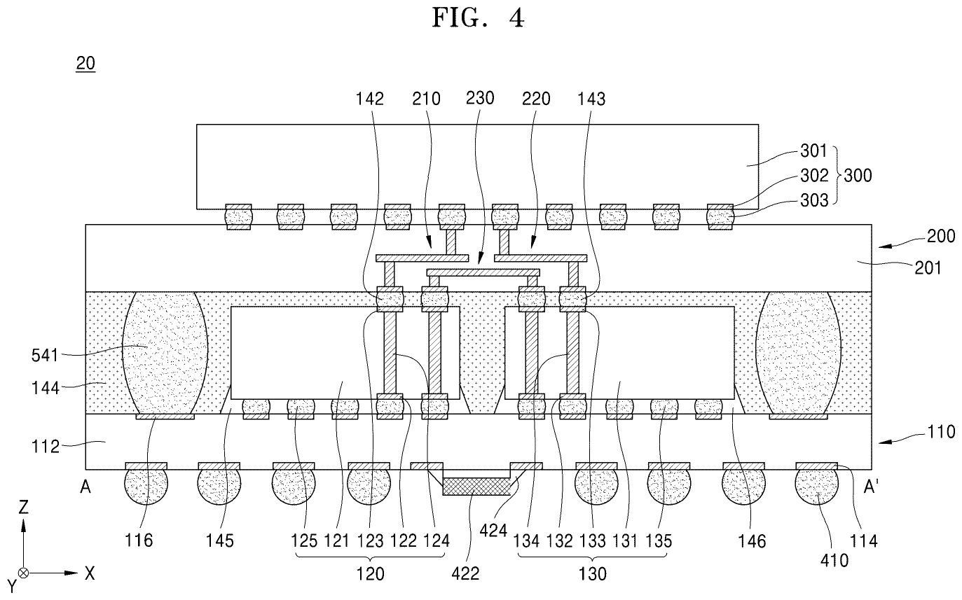

FIG. 4 is a cross-sectional view of a semiconductor package 20 according to some embodiments. The cross-sectional view illustrated in FIG. 4 is a cross-sectional view corresponding to the cross-sectional view of the semiconductor package 10 illustrated in FIG. 2.

The semiconductor package 20 illustrated in FIG. 4 may be almost the same as or similar to the semiconductor package 10 illustrated in FIGS. 2 and 3 except for that the joint ball 141 is replaced with a dummy ball 541 and an interposer 200 does not include the external pattern structure 240. Therefore, descriptions which are the same as or similar to the descriptions of FIGS. 2 and 3 are omitted to avoid repeated descriptions.

Referring to FIG. 4, the semiconductor package 20 may include the dummy ball 541 which is disposed farther away from a center (e.g., a horizontal center point) of the semiconductor package 20 than a first semiconductor chip 120 and a second semiconductor chip 130. In this case, with respect to a horizontal plane (e.g., in the X direction and/or the Y direction), the dummy ball 541 may surround the first semiconductor chip 120 and the second semiconductor chip 130. For example, the dummy ball 541 may surround the first semiconductor chip 120 and the second semiconductor chip 130 in a plan view. The dummy ball 541 may be disposed between a package substrate 110 and an interposer 200. The dummy ball 541 may be spaced apart from a sidewall of the first semiconductor chip 120 and/or the second semiconductor chip 130 in a horizontal direction (e.g., the X direction and/or the Y direction) and may have a pillar shape which extends between the package substrate 110 and the interposer 200. A shape of the dummy ball 541 may be substantially similar to that of the joint ball 141 illustrated in FIG. 2.

A lower surface of the dummy ball 541 may contact a substrate upper pad 116 of the package substrate 110, and an upper portion of the dummy ball 541 may contact an interposer substrate 201. In this case, the upper portion of the dummy ball 541 may contact an insulating material of the interposer substrate 201, instead of contacting a conductive material buried in the interposer substrate 201. Likewise, according to some embodiments, the lower portion of the dummy ball 541 may contact an insulating material of a substrate base 112, instead of contacting the substrate upper pad 116 of the package substrate 110.

The interposer 200 illustrated in FIG. 4 may not include the external pattern structure 240, unlike the interposer 200 illustrated in FIG. 2. Therefore, the dummy ball 541 may not be physically connected with a vertical wiring structure, unlike the joint ball 141 illustrated in FIG. 2. The package substrate 110 illustrated in FIG. 4 may be electrically connected with the interposer 200 and the third semiconductor chip 300 through the first semiconductor chip 120 and the second semiconductor chip 130.

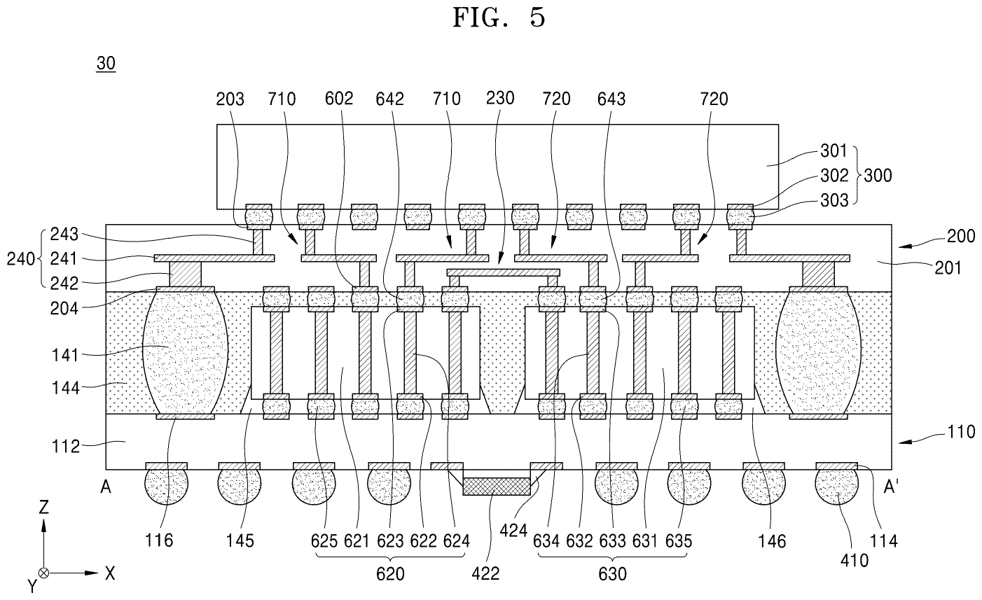

FIG. 5 is a cross-sectional view of a semiconductor package 30 according to some embodiments.

The semiconductor package 30 illustrated in FIG. 5 may be almost the same as or similar to the semiconductor package 10 illustrated in FIGS. 2 and 3 except for that each of a first semiconductor chip 620 and a second semiconductor chip 630 includes a plurality of through vias (for example, a plurality of first through vias 624 and a plurality of second through vias 634, respectively) which are uniformly arranged. Therefore, descriptions which are the same as or similar to the descriptions of FIGS. 2 and 3 are omitted to avoid repeated descriptions.

Referring to FIG. 5, the first semiconductor chip 620 of the semiconductor package 30 may include the plurality of first through vias 624, and the second semiconductor chip 630 may include the plurality of second through vias 634. In this case, unlike the first semiconductor chip 120 illustrated in FIG. 2, the first semiconductor chip 620 illustrated in FIG. 5 may not include the first connection region CA1 and the first non-connection region UCA1 which are divided. Likewise, unlike the second semiconductor chip 130 illustrated in FIG. 2, the second semiconductor chip 630 illustrated in FIG. 5 may not include the second connection region CA2 and the second non-connection region UCA2 which are divided.

The plurality of first through vias 624 may provide a path which passes through a first chip body 621 in a vertical direction (the Z direction) and connects a first lower chip pad 622 with a first upper chip pad 623. With respect to a horizontal plane, the plurality of first through vias 624 of the first semiconductor chip 620 may be uniformly disposed over the first semiconductor chip 620, and thus, the first lower chip pad 622 and the first upper chip pad 623 may be uniformly disposed over the first semiconductor chip 620.

The number of first solder balls 642 and the number of second solder balls 643 may respectively correspond to the number of first through vias 624 and the number of second through vias 634. Therefore, the number of first solder balls 642 and the number of second solder balls 643 illustrated in FIG. 5 may be more than the number of first solder balls 142 and the number of second solder balls 143 illustrated in FIG. 2. Based on the number of first solder balls 642 and the number of second solder balls 643, the number of first connection pads 602 respectively attached on the first solder ball 642 and the second solder ball 643 may increase.

Likewise, the number of first pattern structures 710 and second pattern structures 720 each included in an interposer 200 may be more than the number of first pattern structures 210 and second pattern structures 220 illustrated in FIG. 2. A plurality of the first pattern structures 710 may be electrically connected to respective ones of the first solder balls 642 with respective ones of the first connection pads 602 therebetween, and a plurality of the second pattern structures 720 may be electrically connected to respective ones of the second solder balls 643 with respective ones of the first connection pads 602 therebetween.

A material included in each of the first through via 624 and the second through via 634 illustrated in FIG. 5 may be substantially the same as a material included in each of the first through via 124 and the second through via 134 illustrated in FIG. 2.

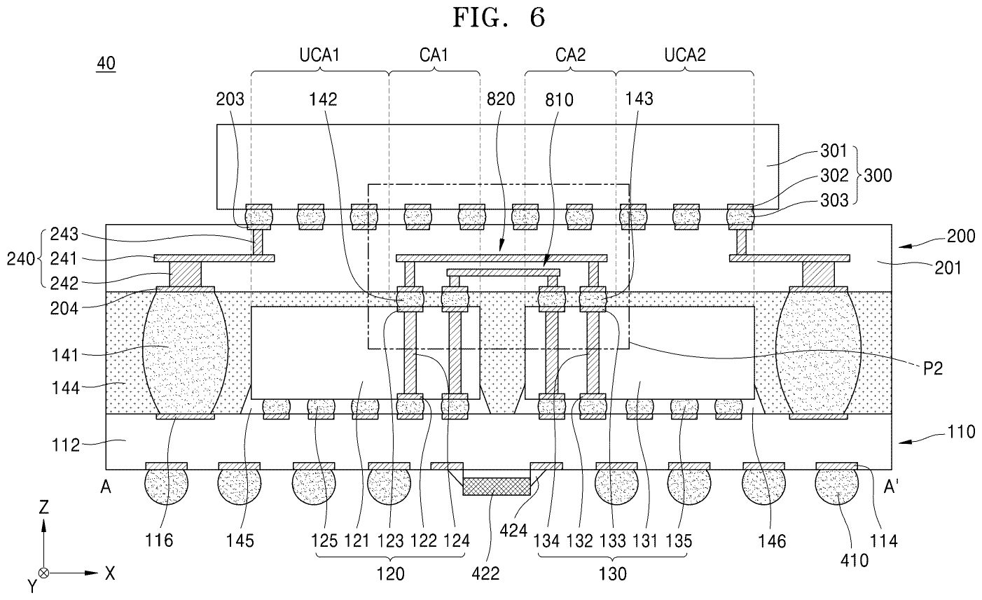

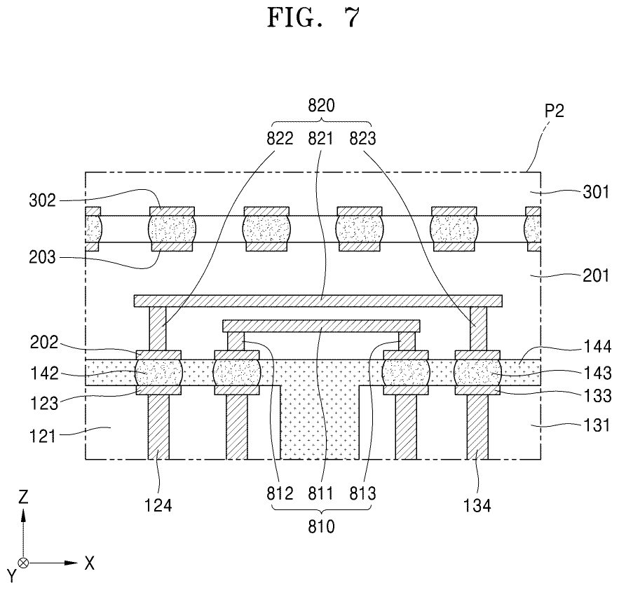

FIG. 6 is a cross-sectional view of a semiconductor package 40 according to some embodiments, and FIG. 7 is an enlarged view of a region P2 of FIG. 6.

The semiconductor package 40 illustrated in FIGS. 6 and 7 may be almost the same as or similar to the semiconductor package 10 illustrated in FIGS. 2 and 3 except for that an interposer 200 does not include a first pattern structure 210 and a second pattern structure 220 which are vertical wiring structures. Therefore, descriptions which are the same as or similar to the descriptions of FIGS. 2 and 3 are omitted to avoid repeated descriptions.

Referring to FIGS. 6 and 7, an interposer 200 may include a first horizontal pattern structure 810 and a second horizontal pattern structure 820, which are a plurality of horizontal wiring structures. In this case, the first horizontal pattern structure 810 and the second horizontal pattern structure 820 may have a structure which is substantially similar to that of the third pattern structure 230 illustrated in FIG. 2. The first horizontal pattern structure 810 and the second horizontal pattern structure 820 may be electrically connected with a first semiconductor chip 120 and a second semiconductor chip 130. With respect to a horizontal plane, the first horizontal pattern structure 810 and the second horizontal pattern structure 820 may overlap the first semiconductor chip 120 and the second semiconductor chip 130 in a vertical direction (the Z direction).

The first horizontal pattern structure 810 may be electrically connected with a first solder ball 142 among a plurality of first solder balls 142 that is disposed closest to a center (e.g., a horizontal center point) of the semiconductor package 40. That is, a first solder ball 142, which is disposed closest to the second semiconductor chip 130 in a lateral direction (the X direction and/or the Y direction), among the plurality of first solder balls 142 may be electrically connected with the first horizontal pattern structure 810. Likewise, the first horizontal pattern structure 810 may be electrically connected with a second solder ball 143 among a plurality of second solder balls 143 that is disposed closest to the center (e.g., the horizontal center point) of the semiconductor package 40. That is, a second solder ball 143, which is disposed closest to the first semiconductor chip 120 in the lateral direction (the X direction and/or the Y direction), among the plurality of second solder balls 143 may be electrically connected with the first horizontal pattern structure 810.

The first horizontal pattern structure 810 may include a first horizontal pattern 811, a first vertical via 812, and a second vertical via 813, which extend longitudinally in the lateral direction (the X direction and/or the Y direction). The first horizontal pattern 811 may have substantially the same structure and configuration as that of the third wiring pattern 231 of the third pattern structure 230 illustrated in FIGS. 2 and 3. The first vertical via 812 may have substantially the same structure and configuration as that of the fifth via 232 illustrated in FIGS. 2 and 3, and the second vertical via 813 may have substantially the same structure and configuration as that of the sixth via 233 illustrated in FIGS. 2 and 3.

The second horizontal pattern structure 820 may be electrically connected with a first solder ball 142 among the plurality of first solder balls 142 that is farther away from a center (e.g., a horizontal center point) of the semiconductor package 40 than the first solder ball 142 electrically connected with the first horizontal pattern structure 810. Also, the second horizontal pattern structure 820 may be electrically connected with a second solder ball 143 among the plurality of second solder balls 143 that is farther away from the center (e.g., the horizontal center point) of the semiconductor package 40 than the second solder ball 143 electrically connected with the first horizontal pattern structure 810.

The second horizontal pattern structure 820 may include a second horizontal pattern 821, a third vertical via 822, and a fourth vertical via 823, which extend longitudinally in the lateral direction (the X direction and/or the Y direction). The second horizontal pattern 821 may have a length which is greater than that of the first horizontal pattern 811 in the lateral direction (the X direction and/or the Y direction). Also, the second horizontal pattern 821 may be disposed at a vertical level which is higher than the first horizontal pattern 811 in a vertical direction (the Z direction), relative to an upper surface of a package substrate 110.

The third vertical via 822 may be disposed to vertically overlap the first semiconductor chip 120. The third vertical via 822 may extend toward the first solder ball 142 from the second horizontal pattern 821. In this case, the third vertical via 822 may be disposed farther away from a sidewall of the second semiconductor chip 130 than the first vertical via 812. Also, because the second horizontal pattern 821 is disposed at a vertical level which is higher than the first horizontal pattern 811, the third vertical via 822—which may be provided as one body (i.e., integrated) with the second horizontal pattern 821—may have a vertical length (in the Z direction) which is greater than that of the first vertical via 812. The fourth vertical via 823 may be disposed to vertically overlap the second semiconductor chip 130. The fourth vertical via 823 may extend toward the second solder ball 143 from the second horizontal pattern 821. In this case, the fourth vertical via 823 may be disposed farther away from a sidewall of the first semiconductor chip 120 than the second vertical via 813. Likewise, like the third vertical via 822, the fourth vertical via 823 may have a vertical length which is greater than that of the second vertical via 813.

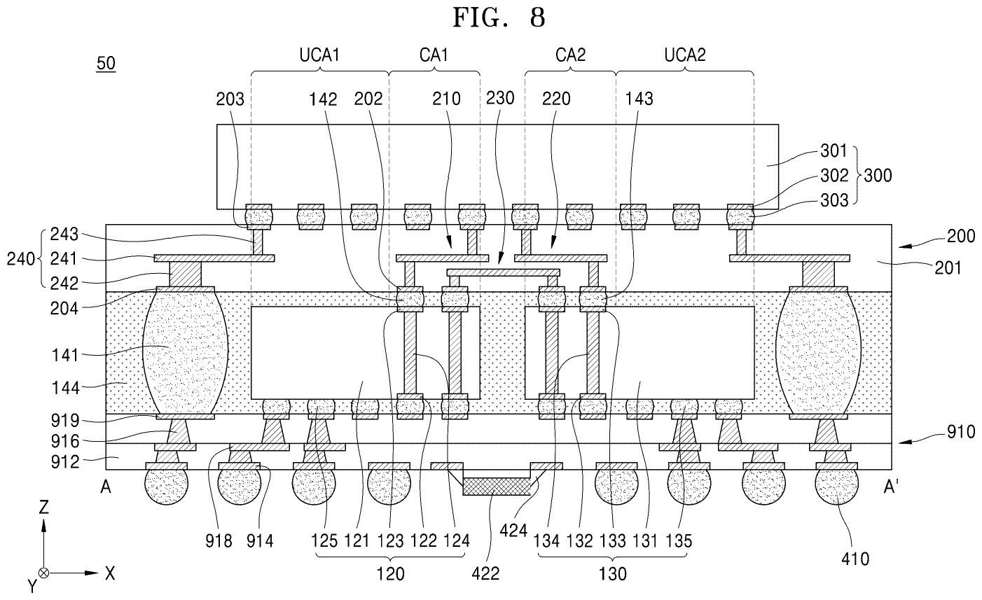

FIG. 8 is a cross-sectional view of a semiconductor package 50 according to some embodiments.

The semiconductor package 50 illustrated in FIG. 8 may be almost the same as or similar to the semiconductor package 10 illustrated in FIGS. 2 and 3 except for that the semiconductor package 50 includes a redistribution substrate 910 instead of a package substrate (see 110 of FIGS. 2 and 3). Therefore, descriptions which are the same as or similar to the descriptions of FIGS. 2 and 3 are omitted to avoid repeated descriptions.

Referring to FIG. 8, the semiconductor package 50 according to some embodiments may include the redistribution substrate 910. The redistribution substrate 910 may include a plurality of insulation layers 912, a lower redistribution pad 914, a redistribution via 916, a redistribution pattern 918, and an upper redistribution pad 919.

A first semiconductor chip 120, a second semiconductor chip 130, an interposer 200, and a third semiconductor chip 300 may be mounted on the redistribution substrate 910. The lower redistribution pad 914, the upper redistribution pad 919, the redistribution via 916, and the redistribution pattern 918 may be in (e.g., may be buried in) the plurality of insulation layers 912. The plurality of insulation layers 912 may be stacked while forming an interface therebetween, or according to some embodiments, the plurality of insulation layers 912 may be provided as one body without forming an interface therebetween.

The plurality of insulation layers 912 may include, for example, an inorganic insulating material such as silicon oxide, silicon nitride, phosphosilicate glass (PSG), boro-phospho-silicate glass (BPSG), fluoride silicate glass (FSG), or a combination thereof, an organic insulating material such as an insulating polymer, or an insulating material including a combination thereof. In some embodiments, the plurality of insulation layers 912 may include a photosensitive material (for example, photosensitive polyimide). When the plurality of insulation layers 912 include the photosensitive material, an opening may be easily formed in the plurality of insulation layers 912 in performing a plating process.

The lower redistribution pad 914 including a conductive material may be disposed on a lower surface of an insulation layer 912 disposed at a lowermost end of the plurality of insulation layers 912. An external connection terminal 410 may be attached on the lower redistribution pad 914. Also, the upper redistribution pad 919 including a conductive material may be disposed on an upper surface of the insulation layer 912 disposed at an uppermost end of the plurality of insulation layers 912. A first chip connection terminal 125, a second chip connection terminal 135, and a joint ball 141 may be attached on the upper redistribution pad 919.

A plurality of the redistribution patterns 918 may extend in a lateral direction (the X direction and/or the Y direction) at different vertical levels, in the insulation layer 912. The redistribution via 916 may physically and electrically connect the redistribution patterns 918 with each other at different vertical levels. The redistribution pattern 918 and the redistribution via 916 may be formed through a plating process, and the redistribution via 916 may include a cross-sectional surface having a tapered shape where a diameter is changed in a vertical direction (the Z direction). In some embodiments, the redistribution via 916 may have a shape where a diameter decreases toward the first semiconductor chip 120 and the second semiconductor chip 130, or alternatively, the redistribution via 916 may have a shape where a diameter increases toward the first semiconductor chip 120 and the second semiconductor chip 130.

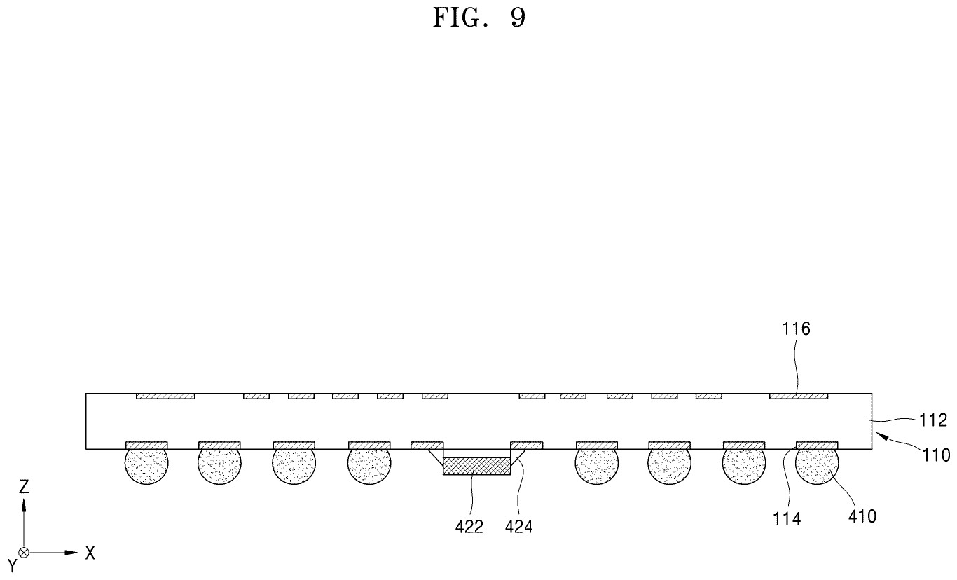

FIGS. 9 to 14 are cross-sectional views illustrating in sequence a method of manufacturing a semiconductor package 10, according to some embodiments.

Referring to FIG. 9, the package substrate 110 may be provided. The package substrate 110 may be, for example, a PCB. Substrate lower pads 114 in (e.g., buried in) a substrate base 112 may be arranged at a lower end of the package substrate 110, and substrate upper pads 116 in (e.g., buried in) the substrate base 112 may be arranged at an upper end of the package substrate 110. The substrate upper pads 116 may be exposed at an upper surface of the substrate base 112, and an external connection terminal 410 and a device connection terminal 424 may be attached on the substrate lower pad 114.

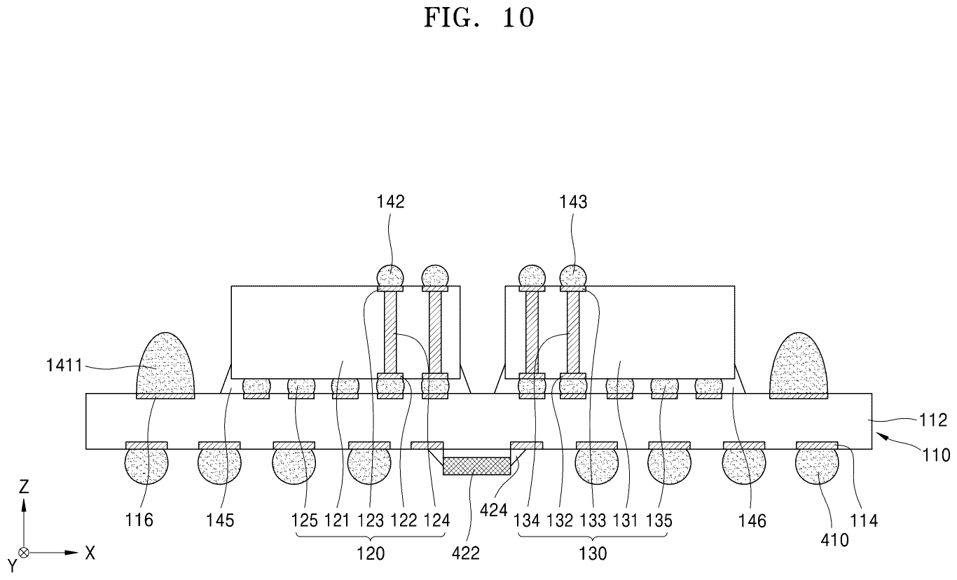

Referring to FIG. 10, a first semiconductor chip 120 and a second semiconductor chip 130 may be mounted on the package substrate 110. The first semiconductor chip 120 and the second semiconductor chip 130 may be mounted on the package substrate 110 by the face-down scheme or the flip chip scheme. An under-fill process may be performed after the first semiconductor chip 120 is mounted on the package substrate 110 and may thus form a first under-fill material layer 145 surrounding a first chip connection terminal 125 disposed between a first chip body 121 and the package substrate 110. Also, an under-fill process may be performed after the second semiconductor chip 130 is mounted on the package substrate 110 and may thus form a second under-fill material layer 146 surrounding a second chip connection terminal 135 disposed between a second chip body 131 and the package substrate 110.

Subsequently, with respect to a horizontal plane, a first sub-ball 1411 may be attached on a substrate upper pad 116 disposed at an outer portion of the upper surface of the package substrate 110. The first sub-ball 1411 may include, for example, a solder, Cu, or the like. Also, a first solder ball 142 may be attached on a first upper chip pad 123 of the first semiconductor chip 120, and a second solder ball 143 may be attached on a second upper chip pad 133 of the second semiconductor chip 130.

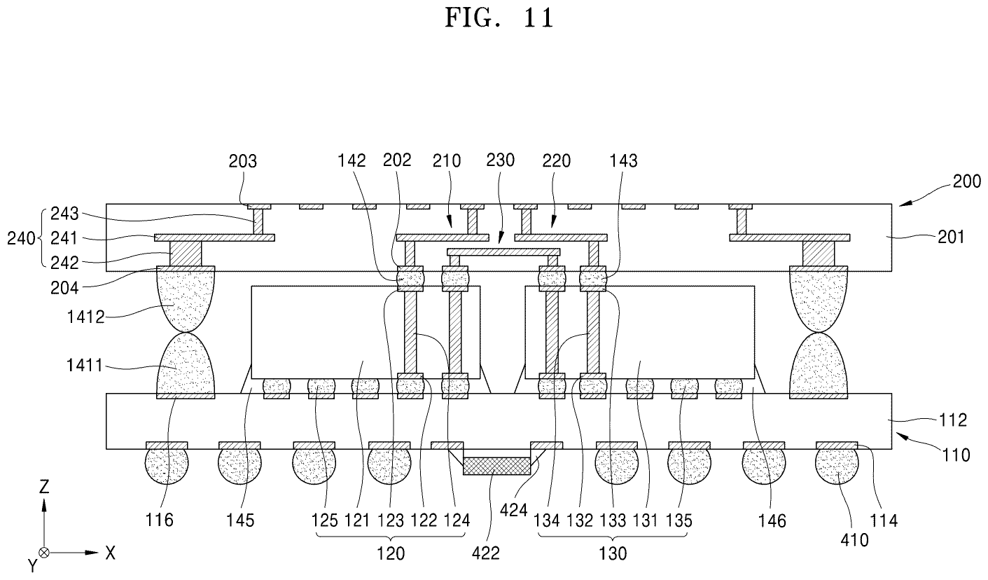

Referring to FIG. 11, an interposer 200 on which a second sub-ball 1412 is attached may be prepared. The second sub-ball 1412 may be attached on an external connection pad 204 of the interposer 200. For example, in order to attach the second sub-ball 1412 on the external connection pad 204, a flux may be coated on the external connection pad 204, and a conductor including a solder or Cu may be attached on the external connection pad 204 through a reflow process. Subsequently, the prepared interposer 200 may be disposed on the first semiconductor chip 120 and the second semiconductor chip 130. At this time, the first solder ball 142 and the second solder ball 143 may be attached on a first connection pad 202 of the interposer 200.

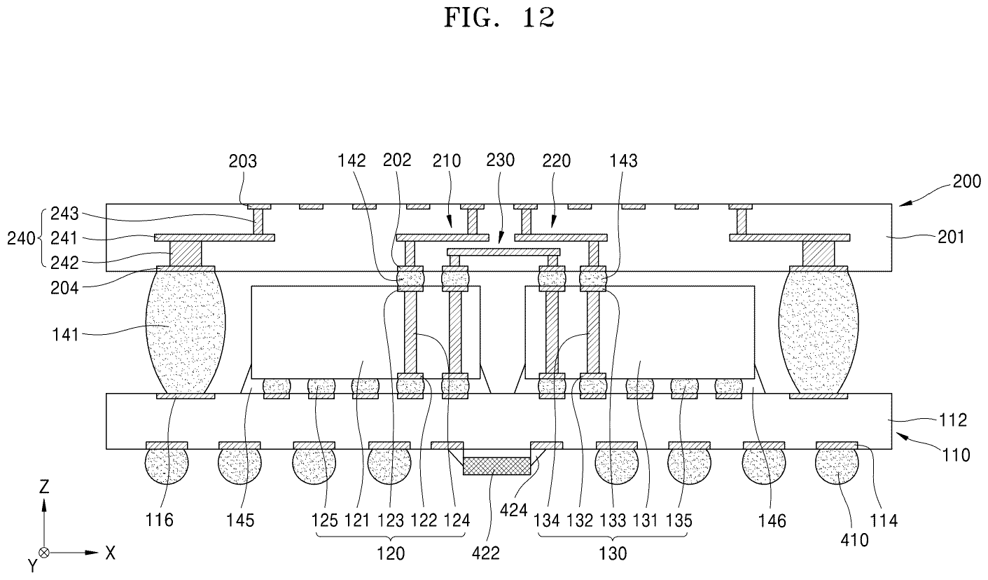

Referring to FIGS. 11 and 12, by performing a thermal compression process, the first sub-ball 1411 may be coupled to the second sub-ball 1412. The first sub-ball 1411 may be coupled to the second sub-ball 1412 through the thermal compression process, and thus, a joint ball 141 may be formed. Based on the thermal compression process, the interposer 200 may be completely mounted on the package substrate 110, and the first semiconductor chip 120 and the second semiconductor chip 130 may be disposed between the package substrate 110 and the interposer 200. While the thermal compression process is being performed, the interposer 200 may be downward pressed by using a mold in a temperature atmosphere which is higher than a room temperature.

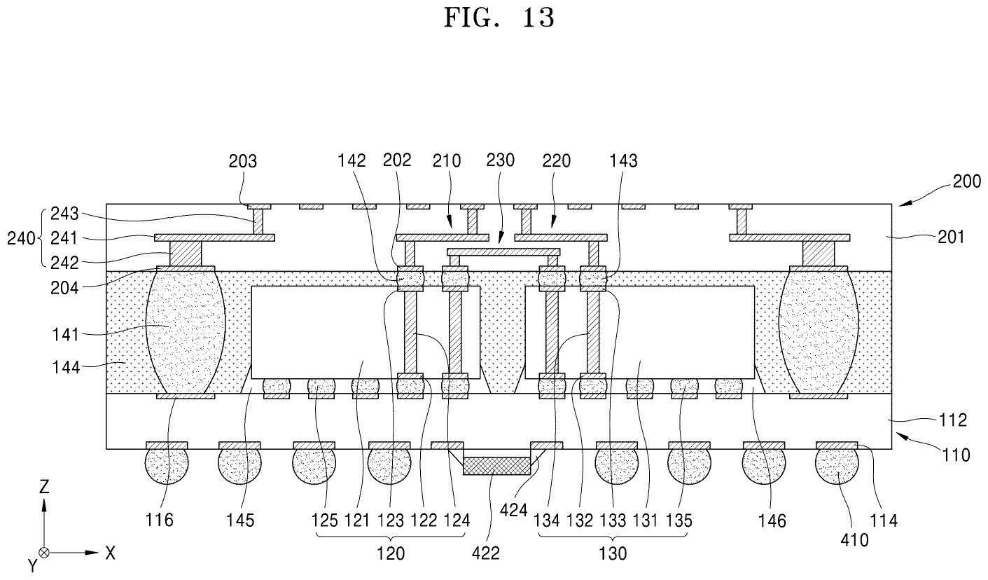

Referring to FIG. 13, a molding layer 144 between (e.g., filled between) the package substrate 110 and the interposer 200 may be formed. For example, in order to form the molding layer 144, a molding material may be supplied between the package substrate 110 and the interposer 200, and then, may be cured. In this case, the molding material may include an insulating filler. In some embodiments, a lower surface of the interposer 200 may be spaced apart from an upper surface of the first semiconductor chip 120 and an upper surface of the second semiconductor chip 130 by the first solder ball 142 and the second solder ball 143, and thus, the molding material may be in a gap between (e.g., may be filled in a gap between) the interposer 200 and the first semiconductor chip 120 and a gap between the interposer 200 and the second semiconductor chip 130.

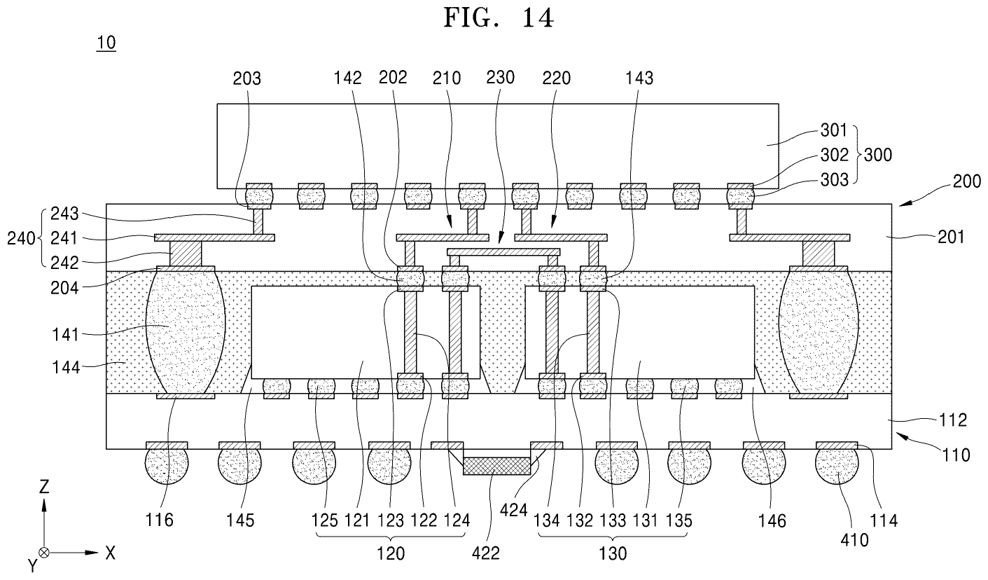

Referring to FIG. 14, a third semiconductor chip 300 may be mounted on the interposer 200. A third chip connection terminal 303 of the third semiconductor chip 300 may be attached on a second connection pad 203 of the interposer 200. It is illustrated that the third semiconductor chip 300 is mounted on the interposer 200 by the flip chip scheme, but the inventive concepts are not limited thereto.

With respect to a horizontal plane, ones of the third chip connection terminals 303 disposed at a center portion of the third semiconductor chip 300 may be electrically connected with a first pattern structure 210 and a second pattern structure 220. Also, with respect to a horizontal plane, ones of the third chip connection terminals 303 disposed at an outer portion of the third semiconductor chip 300 may be electrically connected with an external pattern structure 240.

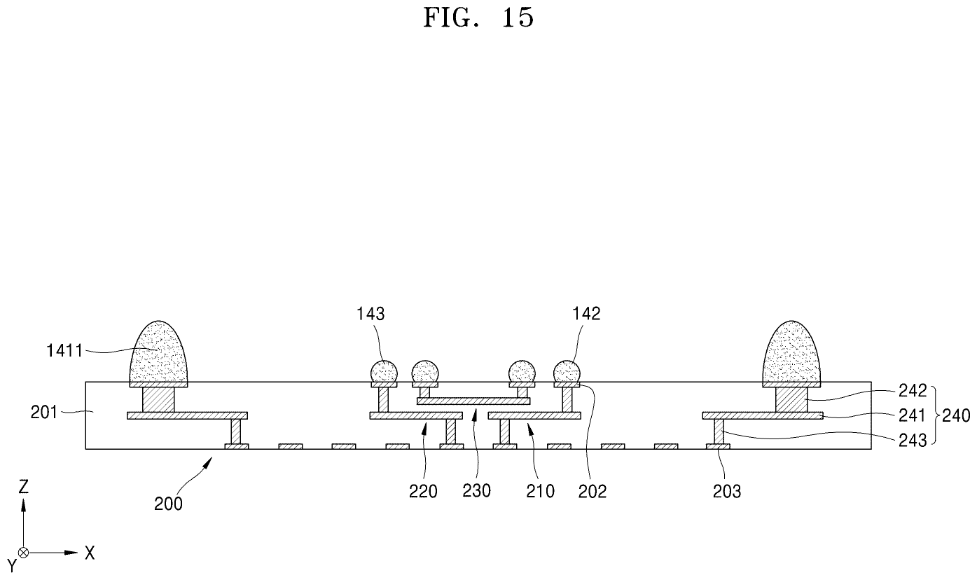

FIGS. 15 to 17 illustrate in sequence a method of manufacturing a semiconductor package, according to some embodiments. Hereinafter, the illustration of a portion which is the same as or similar to the method of manufacturing the semiconductor package illustrated in FIGS. 9 to 14 is omitted to avoid repeated illustrations.

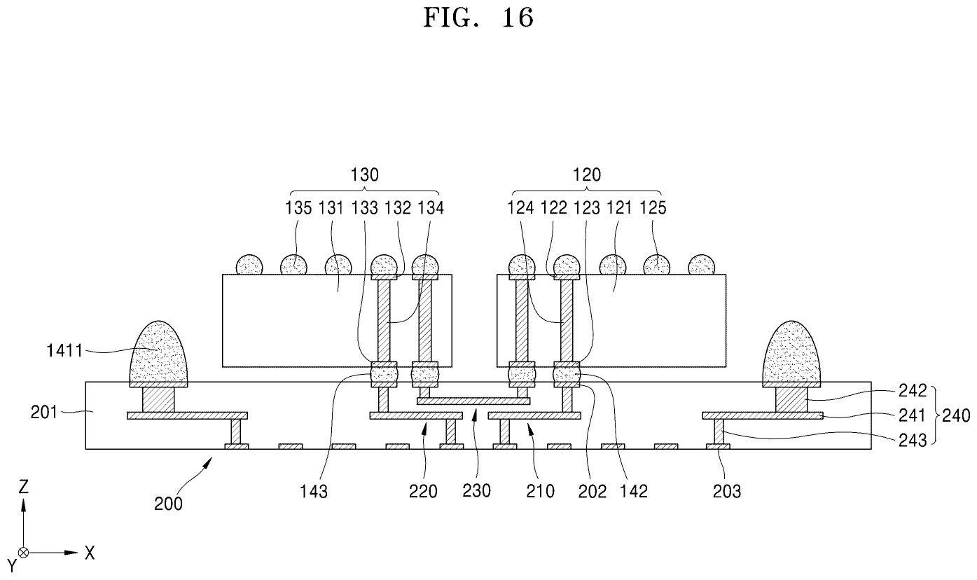

Referring to FIGS. 15 and 16, an interposer 200 on which a first sub-ball 1411, a first solder ball 142, and a second solder ball 143 are attached may be first provided. Unlike the method of manufacturing the semiconductor package illustrated in FIGS. 9 to 14, in the method of manufacturing the semiconductor package illustrated in FIGS. 15 to 17, a first semiconductor chip 120 and a second semiconductor chip 130 may be mounted on the interposer 200 instead of a package substrate 110. At this time, a first upper chip pad 123 of the first semiconductor chip 120 and a second upper chip pad 133 of the second semiconductor chip 130 may be attached on the first solder ball 142 and the second solder ball 143, respectively.

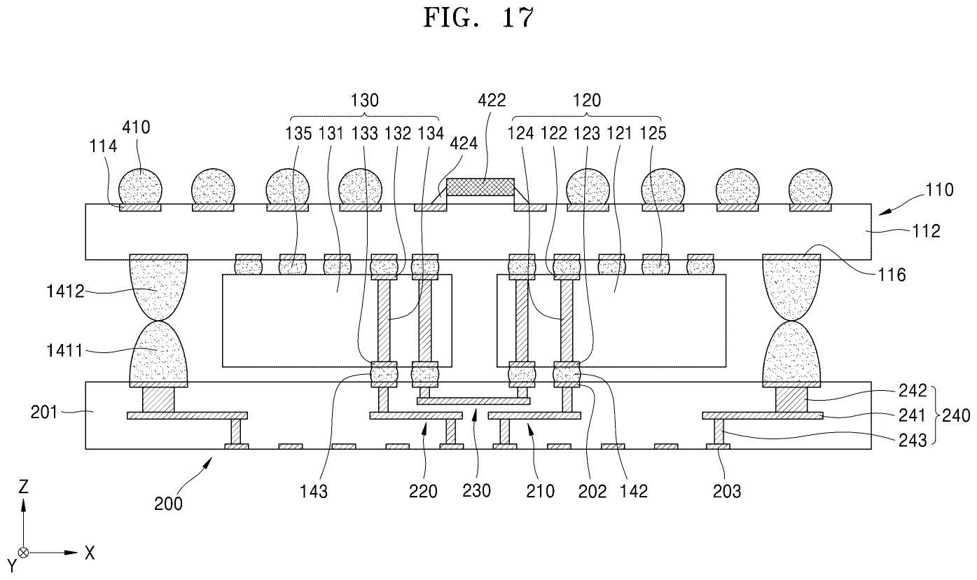

Referring to FIG. 17, the package substrate 110 on which the second sub-ball 1412 is attached may be aligned and attached on the first semiconductor chip 120 and the second semiconductor chip 130. At this time, a substrate upper pad 116 of the package substrate 110 may be attached on a joint ball 141, a first chip connection terminal 125, and a second chip connection terminal 135. Also, the first sub-ball 1411 may be attached on the second sub-ball 1412, and then, the joint ball 141 (see FIG. 12) may be formed by a thermal compression process.

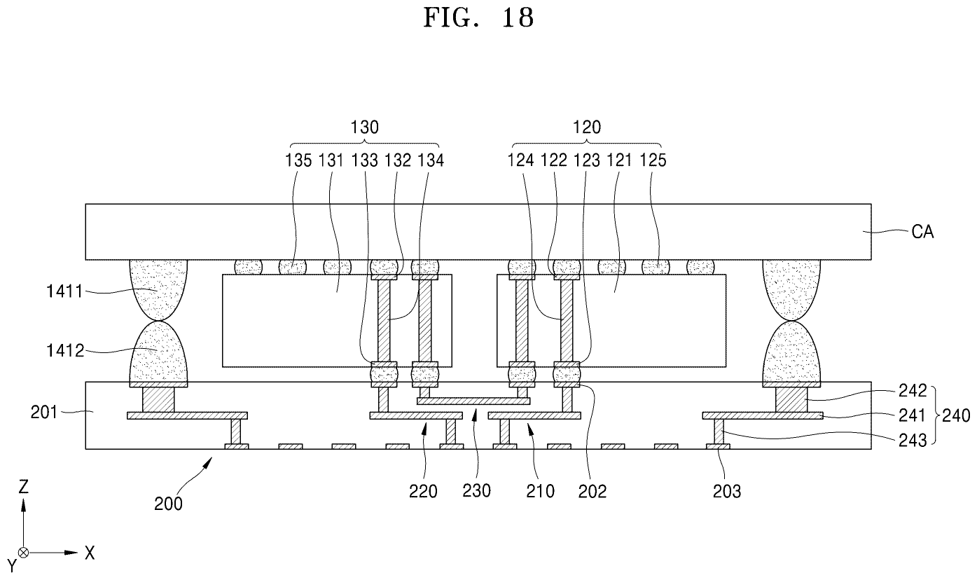

FIGS. 18 to 20 illustrate in sequence a method of manufacturing a semiconductor package, according to some embodiments. Hereinafter, the illustration of a portion which is the same as or similar to the method of manufacturing the semiconductor package illustrated in FIGS. 9 to 14 is omitted to avoid repeated illustrations.

Referring to FIG. 18, an interposer 200 with a first semiconductor chip 120 and a second semiconductor chip 130 mounted thereon may be provided. At this time, the first semiconductor chip 120 and the second semiconductor chip 130 may be attached on a carrier substrate CA. In detail, a first chip connection terminal 125 of the first semiconductor chip 120 and a second chip connection terminal 135 of the second semiconductor chip 130 may be attached on the carrier substrate CA. Also, the first sub-ball 1411 may be attached on the carrier substrate CA. Although not shown in detail, an adhesive film may be attached on the carrier substrate CA. At this time, the first chip connection terminal 125, the second chip connection terminal 135, and the first sub-ball 1411 may be attached on the adhesive film. The adhesive film may be, for example, a thermo-curable adhesive tape where an adhesive force is weakened by thermal treatment and an ultraviolet (UV)-curable adhesive tape where an adhesive force is weakened by UV irradiation.

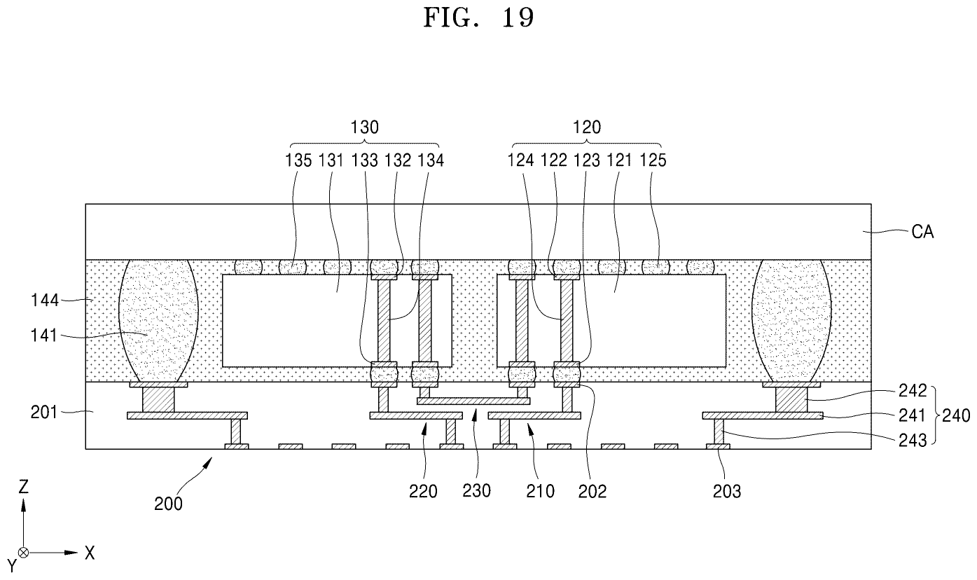

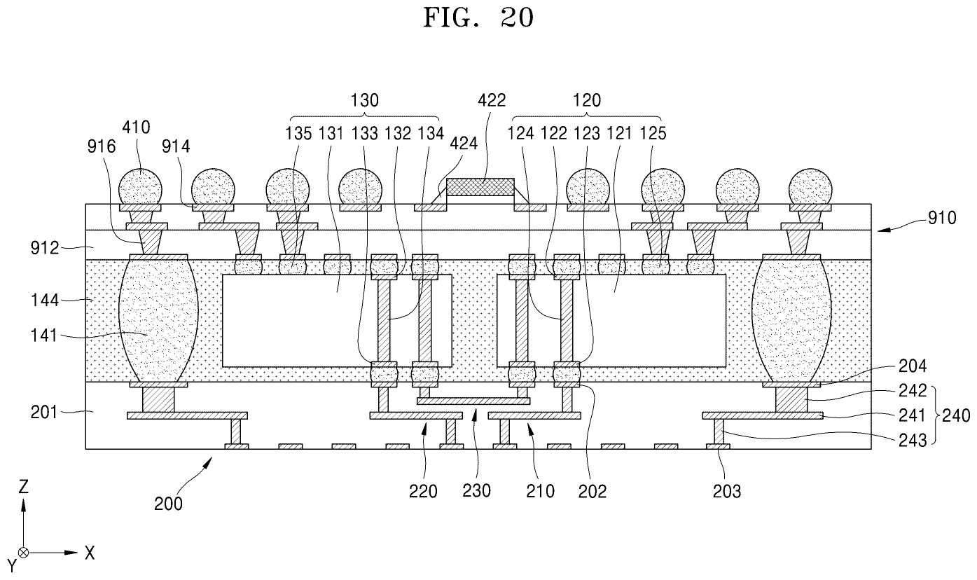

Subsequently, referring to FIGS. 19 and 20, a molding layer 144 may be formed by filling a molding material between the interposer 200 and the carrier substrate CA. The molding layer 144 may be in (e.g., may fill) a space between the carrier substrate CA and the first semiconductor chip 120 and a space between the carrier substrate CA and the second semiconductor chip 130. Also, the molding layer 144 may be in (e.g., may fill) a space between the interposer 200 and the first semiconductor chip 120 and a space between the interposer 200 and the second semiconductor chip 130.

Subsequently, the carrier substrate CA may be removed, and then, a redistribution substrate 910 may be formed on the first semiconductor chip 120 and the second semiconductor chip 130 through a redistribution process. The redistribution process of forming the redistribution substrate 910 may include a photoresist process and a plating process.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

Hereinabove, example embodiments have been described in the drawings and the specification. Embodiments have been described by using the terms described herein, but this has been merely used for describing the inventive concepts and has not been used for limiting a meaning or limiting the scope of the inventive concepts defined in the following claims. Therefore, it may be understood by those of ordinary skill in the art that various modifications and other equivalent embodiments may be implemented from the inventive concepts. Accordingly, the scope of the inventive concepts may be defined based on the scope of the following claims.

While the inventive concepts have been particularly shown and described with reference to example embodiments thereof, it will be understood that various changes in form and details may be made therein without departing from the scope of the following claims.

What is claimed is:

1. A semiconductor package comprising:
a package substrate;
a first semiconductor chip on the package substrate and including a plurality of first through vias;
a second semiconductor chip spaced apart from the first semiconductor chip in a lateral direction parallel to an upper surface of the package substrate and including a plurality of second through vias;
a third semiconductor chip on the first semiconductor chip;
an interposer between the third semiconductor chip and the first semiconductor chip and electrically connecting the first semiconductor chip to the third semiconductor chip;
a molding layer between the package substrate and the interposer and on the first semiconductor chip and the second semiconductor chip;
a first solder ball between the first semiconductor chip and the interposer; and
a second solder ball between the second semiconductor chip and the interposer,
wherein the interposer comprises:
a first pattern structure that electrically connects the first semiconductor chip to the third semiconductor chip;
a second pattern structure that electrically connects the second semiconductor chip to the third semiconductor chip; and
a third pattern structure that electrically connects the first semiconductor chip to the second semiconductor chip.

2. The semiconductor package of claim 1, wherein the first pattern structure overlaps the first semiconductor chip in a vertical direction perpendicular to the upper surface of the package substrate and does not overlap the second semiconductor chip in the vertical direction,
wherein the second pattern structure overlaps the second semiconductor chip in the vertical direction and does not overlap the first semiconductor chip in the vertical direction, and
wherein the third pattern structure overlaps a portion of the first semiconductor chip and a portion of the second semiconductor chip in the vertical direction.

3. The semiconductor package of claim 1, wherein an upper surface of the first semiconductor chip comprises:
a first connection region that overlaps the plurality of first through vias in a vertical direction perpendicular to the upper surface of the package substrate; and
a first non-connection region that is a region other than the first connection region, and
wherein the first non-connection region is wider than the first connection region in the lateral direction.

4. The semiconductor package of claim 3, wherein the first connection region is closer to the second semiconductor chip than the first non-connection region.

5. The semiconductor package of claim 3, wherein the first non-connection region is covered by the molding layer.

6. The semiconductor package of claim 1, wherein an upper surface of the second semiconductor chip comprises:
a second connection region that overlaps the plurality of second through vias in a vertical direction perpendicular to the upper surface of the package substrate; and
a second non-connection region that is a region other than the second connection region, and
wherein the second non-connection region is wider than the second connection region in the lateral direction.

7. The semiconductor package of claim 1, wherein the first solder ball is one of a plurality of first solder balls between the first semiconductor chip and the interposer,
wherein the second solder ball is one of a plurality of second solder balls between the second semiconductor chip and the interposer,
wherein the interposer further comprises:
a plurality of first connection pads on a lower surface of the interposer and in contact with the plurality of first solder balls, respectively, and the plurality of second solder balls, respectively; and
a plurality of second connection pads on an upper surface of the interposer,
wherein the first pattern structure comprises:
a first wiring pattern extending in the lateral direction;
a first via extending from the first wiring pattern and electrically connected to a first one of the plurality of first connection pads; and
a second via extending from the first wiring pattern and electrically connected to a first one of the plurality of second connection pads, and
wherein the first via overlaps a first one of the plurality of first solder balls in a vertical direction perpendicular to the upper surface of the package substrate.

8. The semiconductor package of claim 7, wherein the second pattern structure comprises:
a second wiring pattern extending in the lateral direction;
a third via extending from the second wiring pattern and electrically connected to a second one of the plurality of first connection pads; and
a fourth via extending from the second wiring pattern and electrically connected to a second one of the plurality of second connection pads, and
wherein the third via overlaps a first one of the plurality of second solder balls in the vertical direction.

9. The semiconductor package of claim 7, wherein the third pattern structure comprises:
a third wiring pattern extending in the lateral direction;
a fifth via extending from the third wiring pattern and electrically connected to a second one of the plurality of first connection pads; and
a sixth via extending from the third wiring pattern and electrically connected to a third one of the plurality of first connection pads, and
wherein the fifth via overlaps a second one of the plurality of first solder balls in the vertical direction, and the sixth via overlaps a first one of the plurality of second solder balls in the vertical direction.

10. The semiconductor package of claim 1, wherein a lower portion of the first solder ball has a width in the lateral direction that decreases toward an upper surface of the first semiconductor chip,
wherein a lower portion of the second solder ball has a width in the lateral direction that decreases toward an upper surface of the second semiconductor chip, and
wherein an upper portion of each of the first solder ball and the second solder ball has a width in the lateral direction that decreases toward the interposer.

11. The semiconductor package of claim 1, wherein each of the first semiconductor chip and the second semiconductor chip comprises a logic chip, and
wherein the third semiconductor chip comprises a memory chip.

12. A semiconductor package comprising:
a package substrate;
a first semiconductor chip on the package substrate and including a plurality of first through vias;
a second semiconductor chip spaced apart from the first semiconductor chip in a lateral direction parallel to an upper surface of the package substrate and including a plurality of second through vias;
a third semiconductor chip on the first semiconductor chip;
an interposer between the first semiconductor chip and the third semiconductor chip and electrically connecting the first semiconductor chip, the second semiconductor chip, and the third semiconductor chip to each other;
a plurality of joint balls surrounding the first semiconductor chip and the second semiconductor chip in a plan view;
a molding layer between the package substrate and the interposer and on the first semiconductor chip, the second semiconductor chip, and at least one of the plurality of joint balls;
a first solder ball between the first semiconductor chip and the interposer; and
a second solder ball between the second semiconductor chip and the interposer,
wherein the interposer comprises:
a first pattern structure overlapping the first semiconductor chip in a vertical direction perpendicular to the upper surface of the package substrate and electrically connecting the first semiconductor chip to the third semiconductor chip;
a second pattern structure overlapping the second semiconductor chip in the vertical direction and electrically connecting the second semiconductor chip to the third semiconductor chip;
a third pattern structure overlapping the first semiconductor chip and the third semiconductor chip in the vertical direction and electrically connecting the first semiconductor chip to the second semiconductor chip; and
an interposer substrate having the first pattern structure, the second pattern structure, and the third pattern structure therein.

13. The semiconductor package of claim 12, wherein the interposer further comprises:
an external connection pad on a lower surface of the interposer substrate and in contact with one of the plurality of joint balls;
an external via electrically connected to the external connection pad;
a first connection pad on the lower surface of the interposer substrate and in contact with the first solder ball; and
a second connection pad on an upper surface of the interposer substrate,
wherein the first pattern structure comprises:
a first wiring pattern extending in the lateral direction;
a first via extending from the first wiring pattern and electrically connected to the first connection pad; and
a second via extending from the first wiring pattern and electrically connected to the second connection pad, and
wherein the first via overlaps the first solder ball in the vertical direction.

14. The semiconductor package of claim 13, wherein a width of the external via in the lateral direction is greater than a width of the first via in the lateral direction.

15. The semiconductor package of claim 12, wherein a lower portion of the at least one of the plurality of joint balls has a width in the lateral direction that decreases toward the package substrate, and
wherein an upper portion of the at least one of the plurality of joint balls has a width in the lateral direction that decreases toward the interposer.

16. The semiconductor package of claim 12, wherein the at least one of the plurality of joint balls is a dummy ball.

17. The semiconductor package of claim 16, wherein an upper portion of the at least one of the plurality of joint balls contacts the interposer substrate.

18. The semiconductor package of claim 12, wherein the third pattern structure is on the first semiconductor chip and the second semiconductor chip.

19. A semiconductor package comprising:
a package substrate;
a first logic chip on the package substrate and including a plurality of first through vias;
a second logic chip spaced apart from the first logic chip in a lateral direction parallel to an upper surface of the package substrate and including a plurality of second through vias;
a memory chip on the first logic chip and the second logic chip, the memory chip including an upper surface that is wider in the lateral direction than an upper surface of at least one of the first logic chip or the second logic chip;
an interposer between the first logic chip and the memory chip and electrically connecting the first logic chip, the second logic chip, and the memory chip to each other;
a plurality of joint balls surrounding the first logic chip and the second logic chip in a plan view;
a first solder ball between the first logic chip and the interposer;
a second solder ball between the second logic chip and the interposer; and
a molding layer between the package substrate and the interposer and on the first logic chip, the second logic chip, at least one of the plurality of joint balls, the first solder ball, and the second solder ball,
wherein the interposer comprises:
a first pattern structure overlapping the first logic chip in a vertical direction perpendicular to the upper surface of the package substrate and electrically connecting the first logic chip to the memory chip;
a second pattern structure that electrically connects the second logic chip to the memory chip;
a third pattern structure that electrically connects the first logic chip to the second logic chip;
an external connection pad on a lower surface of the interposer and in contact with one of the plurality of joint balls;
an external via electrically connected to the external connection pad;
a first connection pad on the lower surface of the interposer and in contact with the first solder ball;
a second connection pad on an upper surface of the interposer; and
an interposer substrate having the first pattern structure, the second pattern structure, the third pattern structure, the external connection pad, the external via, the first connection pad, and the second connection pad therein.

20. The semiconductor package of claim 19, wherein the first connection pad is one of a plurality of first connection pads on the lower surface of the interposer,
wherein the second connection pad is one of a plurality of second connection pads on the upper surface of the interposer,
wherein the first pattern structure comprises:
a first wiring pattern extending in the lateral direction;
a first via extending from the first wiring pattern and electrically connected to a first one of the plurality of first connection pads; and
a second via extending from the first wiring pattern and electrically connected to a first one of the plurality of second connection pads,
wherein the second pattern structure comprises:
a second wiring pattern extending in the lateral direction;
a third via extending from the second wiring pattern and electrically connected to a second one of the plurality of first connection pads; and
a fourth via extending from the second wiring pattern and electrically connected to a second one of the plurality of second connection pads, and
wherein the third pattern structure comprises:
a third wiring pattern extending in the lateral direction;
a fifth via extending from the third wiring pattern, electrically connected to a third one of the plurality of first connection pads, and overlapping the first solder ball; and
a sixth via extending from the third wiring pattern, electrically connected to a fourth one of the plurality of first connection pads, and overlapping the second solder ball.
